(19) United States
(12) Patent Application Publication
(10) Pub. No.: US 2024/0364075 A1
(43) Pub. Date: Oct. 31, 2024

(54) Switchable Laser Driver

(71) Applicant: Abdellatif El Moznine, Cupertino, CA (US)

(72) Inventor: Abdellatif El Moznine, Cupertino, CA (US)

(21) Appl. No.: 18/635,157

(22) Filed: Apr. 15, 2024

Related U.S. Application Data
(60) Provisional application No. 63/462,767, filed on Apr. 28, 2023.

(51) Int. Cl. H01S 5/042

(52) U.S. Cl. CPC H01S 5/0427

(57) ABSTRACT

A switchable laser driver includes one or more pre-drivers, two or more signal interrupters coupled with the pre-driver(s), and two or more drivers coupled with the signal interrupters. By selecting a signal from a pre-driver instead of from a driver, the switchable laser driver maintains its speed.

A DC-coupled laser driver for a directly modulated laser (DML) couples an inductor, the DML, and a bias current sink in series. The anode and cathode of the DML are coupled with two outputs of a current switch, and two termination circuits, each including a termination resistor in series with a capacitor.

### REFERENCES

This application claims priority from U.S. provisional patent application Ser. No. 63/462,767, entitled “A Switchable Laser Driver”, filed on Apr. 28, 2023.

The priority application is hereby incorporated by reference, as if it is set forth in full in this specification.

Each publication, patent, and/or patent application mentioned in this specification is herein incorporated by reference in its entirety to the same extent as if each individual publication and/or patent application was specifically and individually indicated to be incorporated by reference.

### BACKGROUND

### Technical Field

The disclosed implementations relate generally to devices and methods used in optical communication, and in particular to those for optical transceivers.

### Context

The subject matter discussed in this section should not be assumed to be prior art merely as a result of its mention in this section. Similarly, a problem mentioned in this section or associated with the subject matter provided as background should not be assumed to have been previously recognized in the prior art. The subject matter in this section merely represents different approaches, which in and of themselves can also correspond to implementations of the claimed technology.

Electronic systems communicate large amounts of data, increasingly using optical fibers to meet speed and power requirements. An integrated circuit (IC), for example manufactured in silicon or in a III-V semiconductor material, includes a driver circuit that converts a digital bitstream to an analog signal suitable for driving a laser, or a silicon photonic IC. The laser may be, for example, a laser diode, a directly modulated laser (DML), an electro-absorption modulated laser (EML), or a vertical-cavity surface-emitting laser (VCSEL).

In some systems, multiple fibers interface with a single system-on-a-chip (SoC), but data transmission is needed to only one destination at a time or, in case of a redundant network, to only two of multiple available destinations at the same time.

### BRIEF DESCRIPTION OF THE DRAWINGS

The invention will be described with reference to the drawings, in which:

FIG. 1 illustrates an example an example electronic system with a pre-driver circuit, two or more signal interruption circuits, and two or more driver circuits associated with the two or more signal interruption circuits.

FIG. 2 illustrates an example an example electronic system that includes a switched pre-driver circuit with two or more pre-driver circuits, two or more signal interruption circuits associated with the pre-driver circuits, and two or more driver circuits associated with the signal interruption circuits and the pre-driver circuits.

FIG. 3 illustrates an example basic signal interruption circuit (claim 5).

FIG. 4 illustrates an example signal interruption circuit with a voltage-drop device (claim 7).

FIG. 5 illustrates another example signal interruption circuit with a voltage-drop device (claim 8).

FIG. 6 illustrates an example pre-driver circuit.

FIG. 7 illustrates an example of two pre-driver circuits with a common signal input.

FIG. 8 illustrates an example pre-driver circuit with a variable-gain amplifier (VGA) such as used for an automatic gain control (AGC).

FIG. 9 illustrates an example directly modulated laser driver (DML driver).

FIG. 10 illustrates an example DML driver with a voltage-drop device.

FIG. 11 illustrates an example DML driver with a pass transistor.

FIG. 12 illustrates an example electro-absorption modulated laser (EML) driver.

FIG. 13 illustrates another example EML driver.

FIG. 14 illustrates an example driver with a modulator in a photonics IC.

In the figures, like reference numbers may indicate functionally similar elements. The systems and methods illustrated in the figures, and described in the Detailed Description below, may be arranged and designed in a wide variety of different implementations. Neither the figures, nor the Detailed Description, are intended to limit the scope as claimed. Instead, they merely represent examples of different implementations of the invention.

### DETAILED DESCRIPTION

It is very common for electronic systems to include a demultiplexer function, where a signal can be sent to one of several destinations, dependent on a selector signal. In case of a network that features redundancy, for example the option to send a data stream to a destination via two different paths, the signal may need to be sent to two out of multiple possible destinations. However, no circuit is known that is fast enough to take an output signal from a laser driver and send it towards one or two selected laser devices or photonics ICs. This makes it expensive to build, for example, a router, bridge, or switch that needs to simultaneously send a signal to one or a few selected optical destinations. The technology presented herein presents an affordable solution to this problem that can also prevent costly network downtime needed for slow methods of rerouting signals.

### Terminology

As used herein, the phrase “one of” should be interpreted to mean exactly one of the listed items. For example, the phrase “one of A, B, and C” should be interpreted to mean any of: only A, only B, or only C.

As used herein, the phrases at least one of and one or more of should be interpreted to mean one or more items. For example, the phrase “at least one of A, B, or C” or the phrase “one or more of A, B, or C” should be interpreted to mean any combination of A, B, and/or C. The phrase “at least one of A, B, and C” means at least one of A and at least one of B and at least one of C.

Unless otherwise specified, the use of ordinal adjectives first, second, third, etc., to describe an object, merely refers to different instances or classes of the object and does not imply any ranking or sequence.

The terms “comprising” and “consisting” have different meanings in this patent document. An apparatus, method, or product “comprising” (or “including”) certain features means that it includes those features but does not exclude the presence of other features. On the other hand, if the apparatus, method, or product “consists of” certain features, the presence of any additional features is excluded.

The term “coupled” is used in an operational sense and is not limited to a direct or an indirect coupling. “Coupled to” is generally used in the sense of directly coupled, whereas “coupled with” is generally used in the sense of directly or indirectly coupled. Coupled in an electronic system may refer to a configuration that allows a flow of information, signals, data, or physical quantities such as electrons between two elements coupled to or coupled with each other. In some cases, the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term “connected” is used to indicate a direct connection, such as electrical, optical, electromagnetic, or mechanical, between the things that are connected, without any intervening things or devices.

The term “configured” to perform a task or tasks is a broad recitation of structure generally meaning having circuitry that performs the task or tasks during operation. As such, the described item can be configured to perform the task even when the unit/circuit/component is not currently on or active. In general, the circuitry that forms the structure corresponding to configured to may include hardware circuits, and may further be controlled by switches, fuses, bond wires, metal masks, firmware, and/or software. Similarly, various items may be described as performing a task or tasks, for convenience in the description. Such descriptions should be interpreted as including the phrase configured to.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B”. This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms “substantially”, “close”, “approximately”, “near”, and “about” refer to being within minus or plus 10% of an indicated value, unless explicitly specified otherwise.

The following terms or acronyms used herein are defined at least in part as follows:

“AC”—alternating current—an electric current that reverses its direction regularly or irregularly. “AC” voltages and currents are often used to carry signals, whereas “DC” voltages and currents are often used for biasing active devices in an electronic circuit.

“AGC”—automatic gain control

“ASIC”—application-specific integrated circuit

In the context of this document, the control terminal of a transistor is the base in case of a bipolar transistor, and the gate in case of a field-effect transistor.

In the context of this document, the current input terminal of a transistor is the collector in case of a bipolar transistor, and the drain in case of a field-effect transistor.

In the context of this document, the current output terminal of a transistor is the emitter in case of a bipolar transistor, and the source in case of a field-effect transistor.

“DC”—direct current—an electric current that flows in only one direction. “AC” voltages and currents are often used to carry signals, whereas “DC” voltages and currents are often used for biasing active devices in an electronic circuit.

“DML”—directly-modulated laser

“EML”—electro-absorption modulated laser

“FET”—field-effect transistor

“FPGA”—field-programmable gate array

“IC”—integrated circuit—a monolithically integrated circuit, i.e., a single semiconductor die which may be delivered as a bare die or as a packaged circuit. For the purposes of this document, the term integrated circuit also includes packaged circuits that include multiple semiconductor dies, stacked dies, or multiple-die substrates. Such constructions are now common in the industry, produced by the same supply chains, and for the average user often indistinguishable from monolithic circuits.

“MCM”—multi-chip module

“MOS” transistor—metal-oxide-semiconductor transistor, a type of FET.

“PCB”—printed circuit board

“VCSEL”—vertical-cavity surface-emitting laser

“VGA”—variable-gain amplifier.

### Implementations

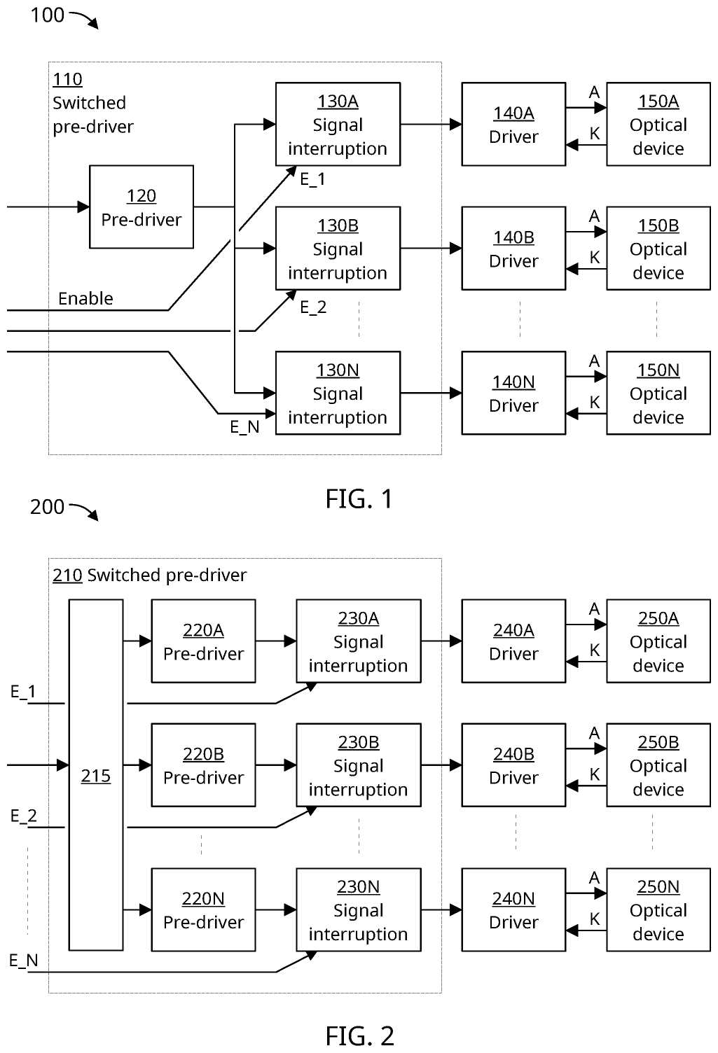

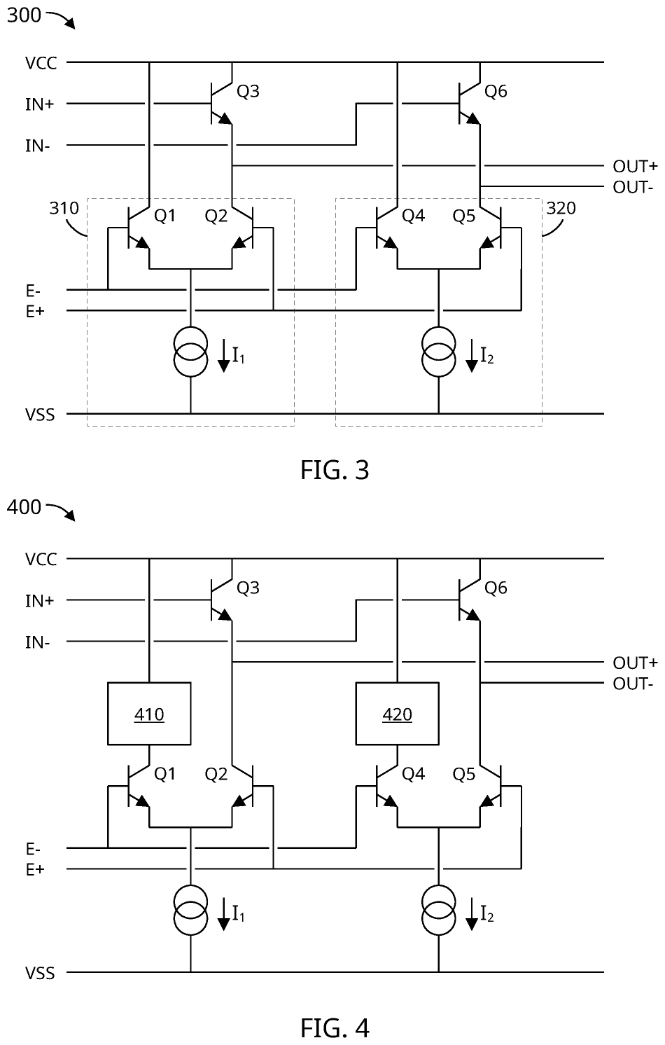

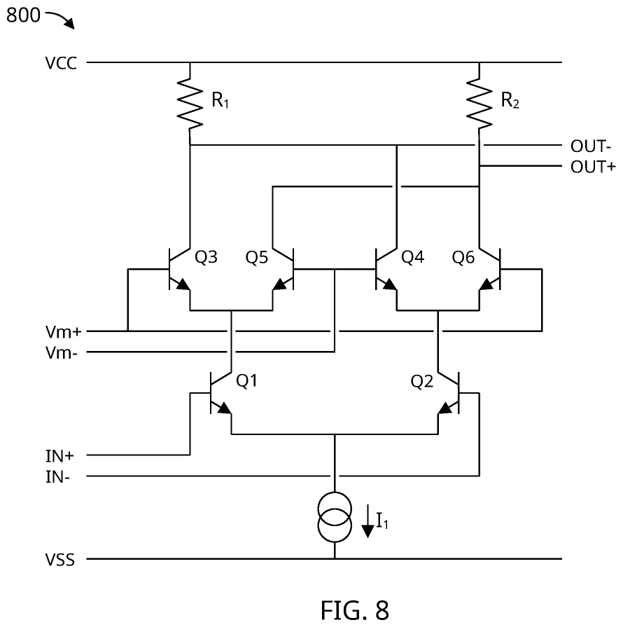

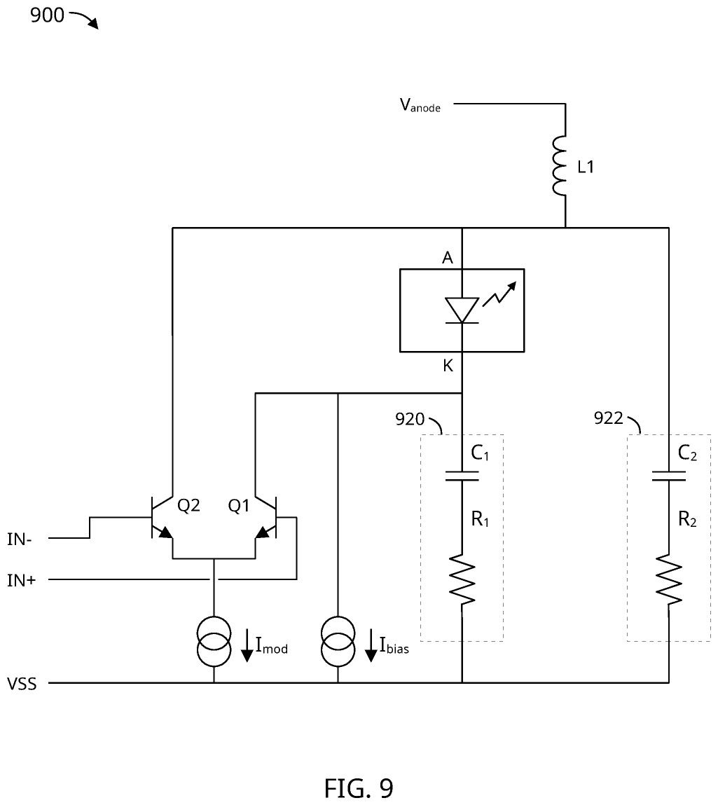

FIG. 1 illustrates an example an example electronic system 100 with a pre-driver circuit 120, two or more signal interruption circuits 130A-N, and two or more driver circuits 140A-N associated with the two or more signal interruption circuits. Pre-driver circuit 120 and signal interruption circuits 130 may be included in a switched pre-driver 110 which has a signal input, two or more enable inputs E_1-E_N, and two or more signal outputs. The two or more driver circuits 140A-N are configured to drive two or more optical devices 150A-N. An optical device may be, for example, a laser diode, a directly-modulated laser (DML), an electro-absorption modulated laser (EML), a vertical-cavity surface-emitting laser (VCSEL), or a silicon-photonics device. An optical device has two terminals, for example an anode terminal (A terminal) and a cathode terminal (K terminal). The signal input of pre-driver circuit 120 is configured to receive an electronic signal to be transmitted as a light signal by one of the optical devices 150. The optical device to transmit the light signal is selected by a signal on the enable inputs. In a typical implementation, each of the optical devices 150 is associated with one of the driver circuits 140, which in turn is associated with one of the signal interruption circuits 130, and one of the enable inputs. Although signals into pre-driver circuit 120 and from there to signal interruption circuits 130A-N and driver circuits 140A-N are drawn with single arrows, implementations may forward signals either as single-ended or as differential signals. Pre-driver circuit 120 may be implemented, for example, as further detailed in reference to FIG. 6 or FIG. 8. Each of the signal interruption circuits 130 may be implemented, for example, as further detailed in reference to FIGS. 3-4. Each of the driver circuits 140 may be implemented, for example, as further detailed in reference to the examples in FIGS. 9-11.

There may be a single pre-driver circuit 120 as shown in FIG. 1, or an implementation may have multiple pre-driver circuits, each associated with one of the signal interruption circuits 130, as shown in FIG. 2.

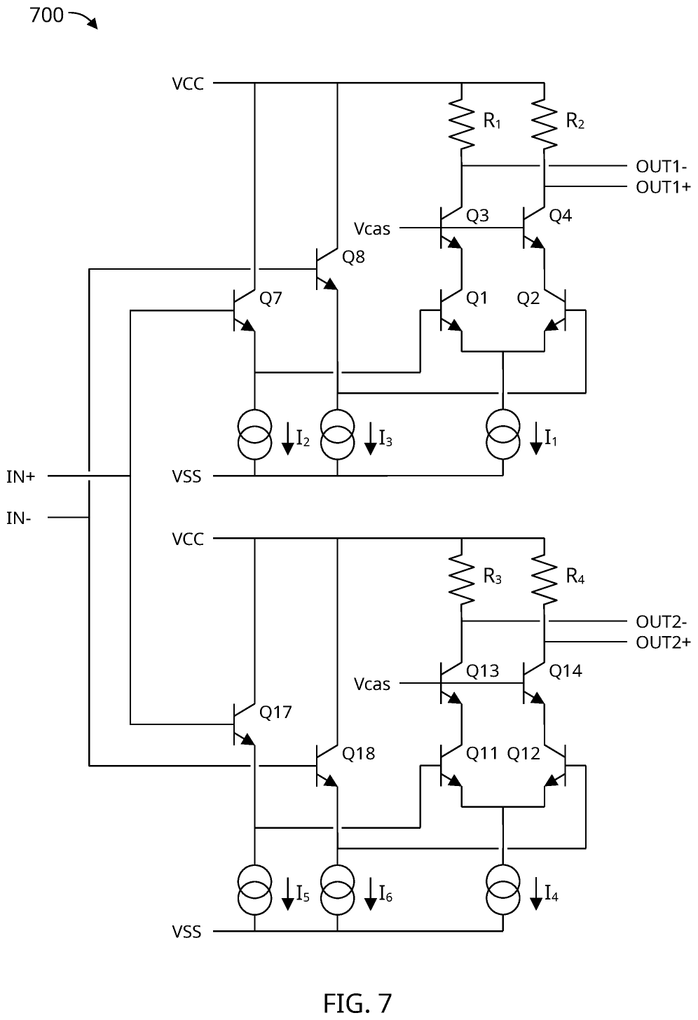

FIG. 2 illustrates an example an example electronic system 200 that includes a switched pre-driver circuit 210 with two or more pre-driver circuits 220A-N, two or more signal interruption circuits 230A-N associated with the pre-driver circuits 220A-N, and two or more driver circuits 240A-N associated with the signal interruption circuits 230A-N and the pre-driver circuits 220A-N. A distributor circuit 215 may distribute an input signal to the pre-driver circuits 220A-N. Although signals into distributor circuit 215 and from there to pre-driver circuits 220A-N, signal interruption circuits 230A-N and driver circuits 240A-N are drawn with single arrows, implementations may forward signals either as single-ended or as differential signals. Each of the pre-driver circuits 220A-N may be implemented, for example, as further detailed in reference to FIG. 6 or FIG. 8. An example implementation of distributor circuit 215 with two pre-driver circuits is shown in FIG. 7. Each of the signal interruption circuits 230 may be implemented, for example, as further detailed in reference to FIGS. 3-5. Each of the driver circuits 240 may be implemented, for example, as further detailed in reference to the examples in FIGS. 9-11.

FIG. 3 illustrates an example basic signal interruption circuit 300. Signal interruption circuit 300 includes a first current switch 310, a second current switch 320, a first transistor Q3, and a second transistor Q6. First current switch 310 has differential current switch inputs (E+ and E−), a first sink output (the Q1 current input terminal—in the case of a bipolar transistor its collector and in the case of a FET its drain), and a second sink output (the Q2 current input terminal—in the case of a bipolar transistor its collector and in the case of a FET its drain). Similarly, second current switch 320 has differential current switch inputs (E+ and E−), a first sink output (the Q4 current input terminal), and a second sink output (the Q5 current input terminal). First transistor Q3 is of a first type, for example the N-type (NPN bipolar transistor, NFET, or NMOS), and second transistor Q6 is of the first type.

The first current switch 310 and second current switch 320 may be coupled with a common node, for example a ground node-here denoted as VSS. Their differential current switch inputs are both coupled with the signal interruption circuit 300 enable input (E+ and E−). Based on the polarity of an enable signal on E+ and E−, either Q1 and Q4 conduct, or Q2 and Q5 conduct. If Q1 and Q4 conduct, the currents I₁ and I₂ are routed from, for example, the voltage supply line—here denoted as VCC. If Q2 and Q5 conduct, the currents I₁ and I₂ are routed through the transistors Q3 and Q6, which will conduct and act as followers (in the case of bipolar transistors, emitter followers; in the case of FETs, source followers). Thus, the OUT+ and OUT− output signals follow the IN+ and IN− input signals.

h-bandwidth semiconductor manufacturing processes, transistors may have a breakdown voltage that is lower than the supply voltage that may be applied to a circuit. For example, when the collectors of Q1 and Q4 are directly coupled with VCC as in FIG. 3, the collector-emitter voltage may temporarily exceed the transistors' collector-emitter breakdown voltage. This problem is prevented in the implementation in FIG. 4.

FIG. 4 illustrates an example signal interruption circuit 400 with a voltage-drop device. Signal interruption circuit 400 has the same topology and functionality as signal interruption circuit 300, with the addition of voltage-drop device 410 coupled between the supply voltage node VCC and the current input terminal of Q1 and voltage-drop device 420 between the supply voltage node VCC and the current input terminal of Q4. A voltage-drop device may be, or include, a diode, a transistor configured as a diode, a resistor, or any circuit that causes a voltage drop between two of its terminals.

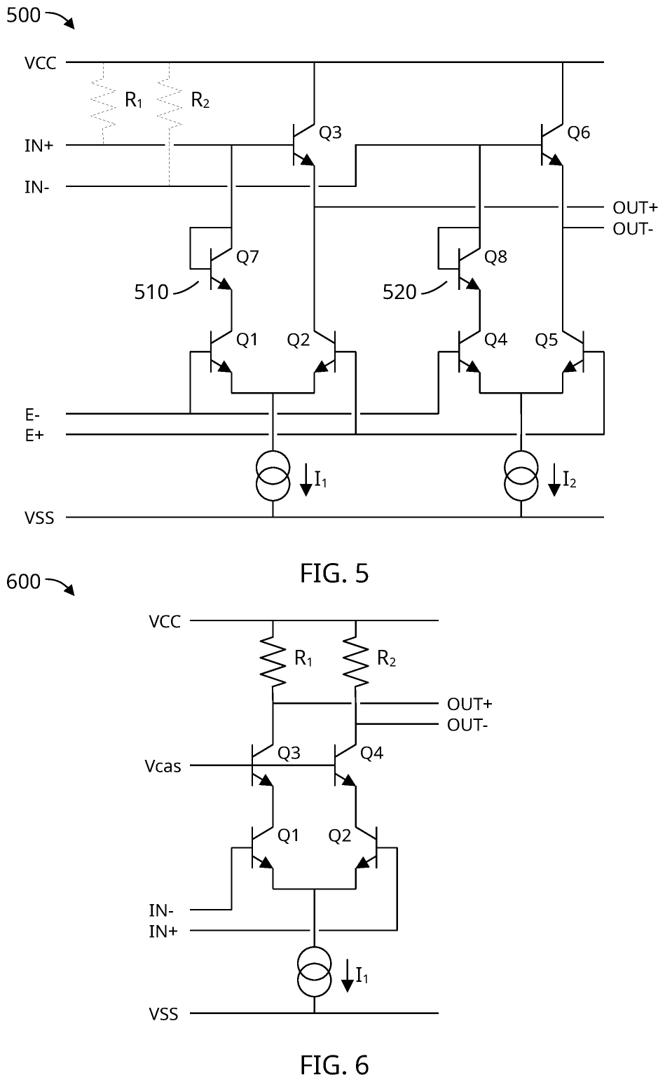

In some cases, a path of conduction may continue to exist through follower devices Q3 and Q6 in FIGS. 3 and 4, even when the signal interruption circuit does not route its current switch currents I₁ and I₂ through the follower devices. In such cases, Q3 and Q6 are not fully turned off, and the OUT+ and OUT− output signals still follow the IN+ and IN− input signals. This problem is prevented in the implementation of FIG. 5.

FIG. 5 illustrates another example signal interruption circuit 500 with a voltage-drop device. The topology and functionality of devices in FIG. 5 is largely the same as in FIG. 4. However, the (optional) voltage-drop devices are not coupled between the supply voltage node and the current switches, but between the input terminals and the current switches. In this example, the first voltage-drop device 510 comprises transistor Q7 which is configured as a diode, and the second voltage-drop device 520 comprises transistor Q8 configured as a diode. The voltage-drop devices may be this configuration, or any of the other possible configuration. When Q1 and Q4 conduct, the currents I₁ and I₂ flow through resistors R1 and R2 that are included in a pre-driver circuit, such as shown in FIGS. 6-8. They are drawn with dotted lines in FIG. 5 because of the shared functionality. When I₁ and I₂ flow through resistors R1 and R2 they cause voltage drops in these resistors, pushing down the voltage on the control terminals (bases) of Q3 and Q6 and fully or substantively pinching these transistors off, so that their follower function is interrupted. The OUT+ and OUT− output signals no longer follow the IN+ and IN− input signals.

FIG. 6 illustrates an example pre-driver circuit 600. It includes a current switch formed by transistors Q1 and Q2, and current sink I₁. The current switch outputs (the current input terminals of Q1 and Q2) are cascoded, i.e., coupled with cascode transistors Q3 and Q4, whose control terminals are coupled with a bias voltage source V_{cas} and grounded for signal frequencies. The cascodes preserves the bandwidth of switching I₁ between load resistor R₁ and load resistor R₂, which are coupled between the cascode transistors and the supply voltage. Additionally, the cascode transistors can protect Q1 and Q2 from collector-emitter voltages that exceed their breakdown values. An implementation may couple the signal outputs OUT+ and OUT− to a signal interruption circuit such as signal interruption circuit 500, signal interruption circuit 300, or signal interruption circuit 400.

FIG. 7 illustrates an example 700 of two pre-driver circuits with a common signal input (IN+ and IN−). This may be an implementation of distributor circuit 215 with pre-driver circuits 220A and -B. The first pre-driver circuit includes devices I₁, Q1-Q4, R₁, and R₂. It also includes a first follower transistor Q7 (an emitter follower in the case of a bipolar transistor, as drawn, or a source follower in the case of a FET), and a second follower transistor Q8. Current sinks I₂ and I₃ are bias devices (some implementations may use current mirrors or bias resistors instead of standalone current sinks). First follower transistor Q7 copies an input voltage signal on IN+ to the control terminal (base) of Q1, and second follower transistor Q8 copies an input voltage signal on IN− to the control terminal (base) of Q2.

Similarly, the second pre-driver circuit includes devices I₄, I₅, I₆, Q11-Q14, Q17, Q18, R3, and R₄. The pre-driver circuits share a common differential input, but have separate differential outputs. Although this example implementation has two pre-driver circuits, other implementations may have any other number of pre-driver circuits and outputs.

FIG. 8 illustrates an example pre-driver circuit 800 with a variable-gain amplifier (VGA) such as used for an automatic gain control (AGC). Again, pre-driver circuit 800 is similar to pre-driver circuit 600, but replaces the cascode transistors with differential pairs in a configuration first published by Howard Jones in U.S. Pat. No. 3,241,078 and later reinvented and further worked out by Barry Gilbert. This configuration, best known as a Gilbert cell or a VGA, allows multiplication of the input signal with another signal, for example a scaler as used in an AGC. The scaler is applied to the Vm+ and Vm− inputs.

FIG. 9 illustrates an example directly modulated laser driver (DML driver 900). DML driver 900 includes a modulation current sink I_{mod}, and a bias current sink I_{bias}, both coupled with a common node such as a ground node (here denoted VSS). In some implementations, I_{mod} and I_{bias} are programmable. DML driver 900 further comprises a first transistor Q1 and a second transistor Q2, which can be for example bipolar transistors (as shown) or FETs, and which may be N-type transistors as shown, or P-type transistors. Note that Q1, Q2, and I_{mod} jointly constitute a current switch, controlled by a differential input voltage signal on the driver input terminals IN+ and IN−. A first termination circuit 920 is coupled between the current input terminal of Q1 and the common node, and a second termination circuit 922 is coupled between the current input terminal of Q2 and the common node. Each first termination circuit 920 and second termination circuit 922 includes a termination resistor R₁ (or R₂) and a capacitor C₁ (or C₂) coupled in series. In some implementations, R₁ is coupled with the common node and C₁ is coupled with the current switch (as shown), and in other implementations, C₁ is coupled with the common node and R₁ is coupled with the current switch. In some implementations, R₁ and R₂ are programmable. This may allow DML driver 900 to interface with, for example, some optical devices that require 250 termination, and others that require 500 termination.

An inductor L1 is coupled between an anode voltage supply V_{anode} and the current input terminal of Q2. The bias current sink I_{bias} is coupled between the common node and the current input terminal of Q1. DML driver 900 further comprises an optical device 910 with a cathode terminal (K terminal) coupled with the Q1 current input terminal and an anode terminal (A terminal) coupled with the Q2 current input terminal. The optical device is a directly modulated laser.

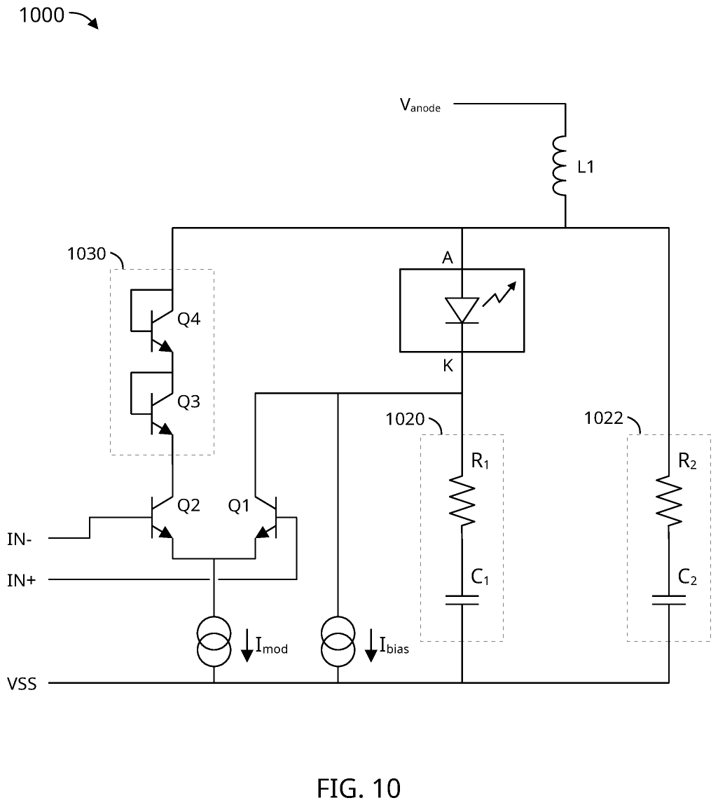

FIG. 10 illustrates an example DML driver 1000 with a voltage-drop device 1030. DML driver 1000 is similar to DML driver 900. Note that in this example, voltage-drop device 1030 includes transistors Q3 and Q4, each configured as a diode. However, other implementations may use any other voltage-drop devices, including diodes, transistors, resistors, and any combination thereof. Note also that in first termination circuit 1020 and second termination circuit 1022 the order of R₁/R₂ and C₁/C₂ is reversed in comparison to first termination circuit 920 and second termination circuit 922. The order of R₁/R₂ and C₁/C₂ is irrelevant for the protection of Q1 and Q2 against overvoltage conditions, and implementations may include either configuration.

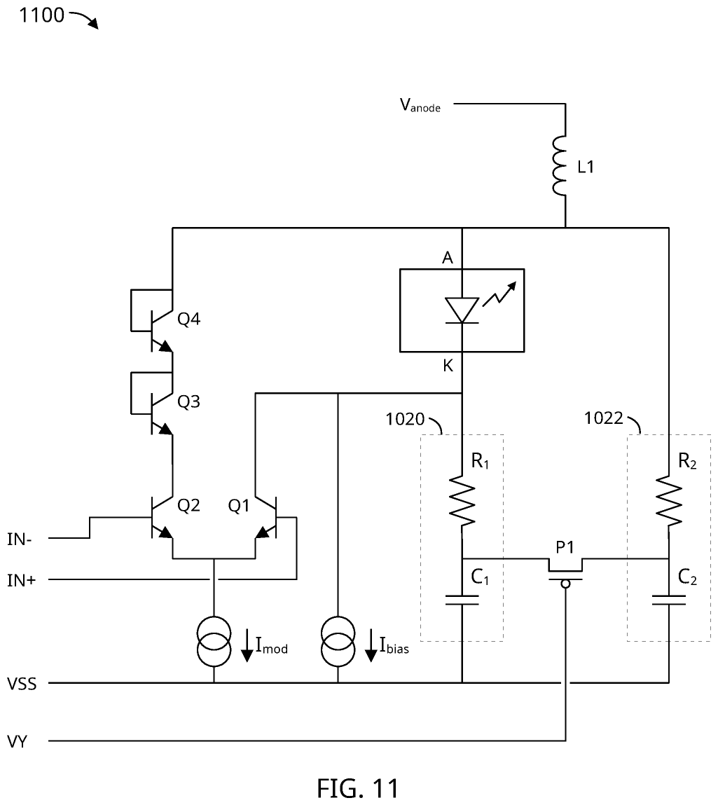

FIG. 11 illustrates an example DML driver 1100 with a pass transistor. DML driver 1100 is mostly the same as DML driver 1000 with the addition of a pass transistor P1, which is here shown as a P-type MOS transistor. In other implementations, the pass transistor may be an N-type transistor. The pass transistor allows for temporarily reducing the voltage over the optical device 1110 so that the anode and the cathode are at nearly the same potential. When asserted (conducting), P1 allows the bias current I_{bias} to run through R₁ and R₂ instead of through optical device 1110.

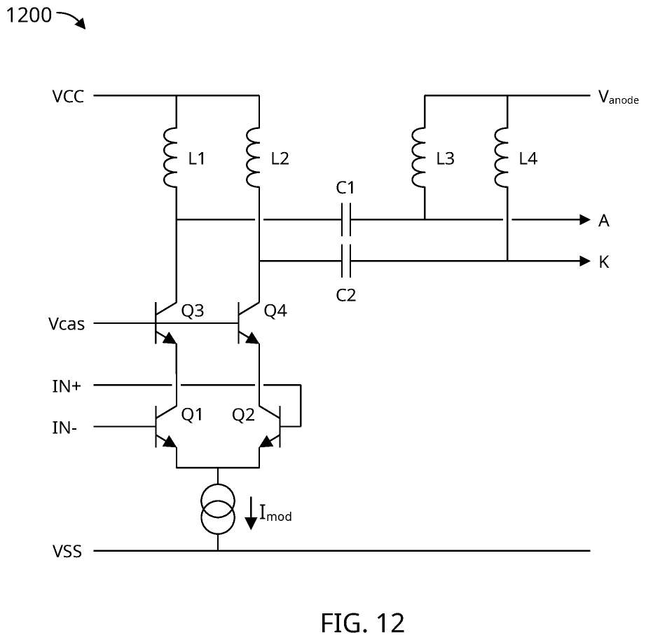

FIG. 12 illustrates an example EML driver 1200. EML driver 1200 includes a modulation current sink I_{mod}, coupled with a common node such as a ground node (here denoted VSS). In some implementations, I_{mod} is programmable. EML driver 1200 further comprises a first transistor Q1 and a second transistor Q2, which can be for example bipolar transistors (as shown) or FETs, and which may be N-type transistors as shown, or P-type transistors. Note that Q1, Q2, and I_{mod} jointly constitute a current switch, controlled by a differential input voltage signal on the driver input terminals IN+ and IN−. The current switch outputs (the current input terminals of Q1 and Q2) are cascoded, i.e., coupled with cascode transistors Q3 and Q4, whose control terminals are coupled with a bias voltage source V_{cas} and grounded for signal frequencies. The cascodes preserves the bandwidth of switching I_{mod} between the respective loads of Q3 and Q4. The filter formed by L1-L4 and C₁-C₂ directs the AC part of the output signal into the A and K terminals of the electro-absorption laser (not drawn), whereas the DC current for Q3 and Q4 travels through L1 and L2. The capacitors C₁ and C₂ block the DC part, so that the laser can be coupled with its own supply voltage V_{anode}. In some implementations, I_{mod} is programmable. Whereas FIG. 12 provides a typical example of an EML driver, many other implementations exist and are known in the art. Each of those may be used in the example architectures of FIGS. 1 and 2.

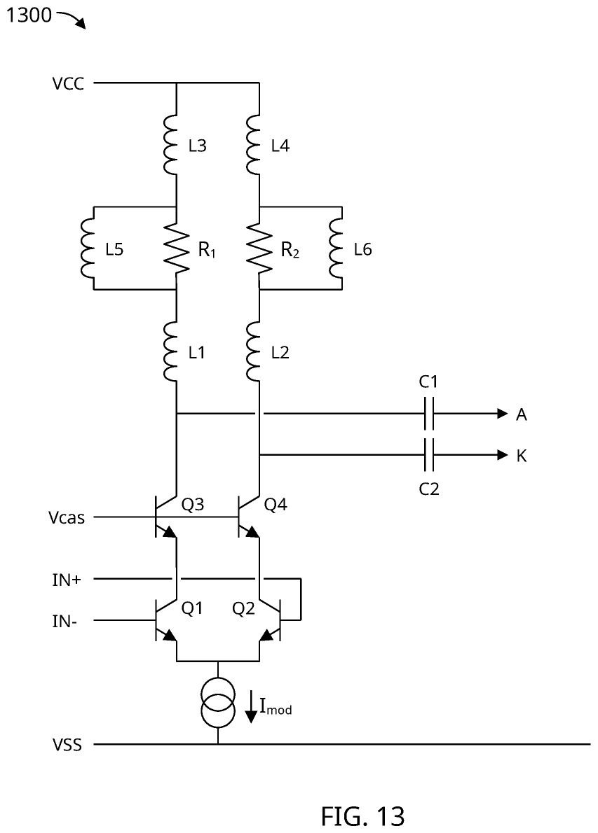

FIG. 13 illustrates another example EML driver 1300. Again, transistors Q1-Q4 and I_{mod} mod form a cascoded current switch that switches the modulation current I_{mod} between its outputs that may be coupled with the A and K terminals of an EML. The capacitors C₁ and C₂ provide DC separation between the driver and the laser. The network L1-L6 and R₁, R₂ provide a filter that loads Q3 and Q4 with R₁ and R₂ for DC currents, and with a high impedance for AC signals.

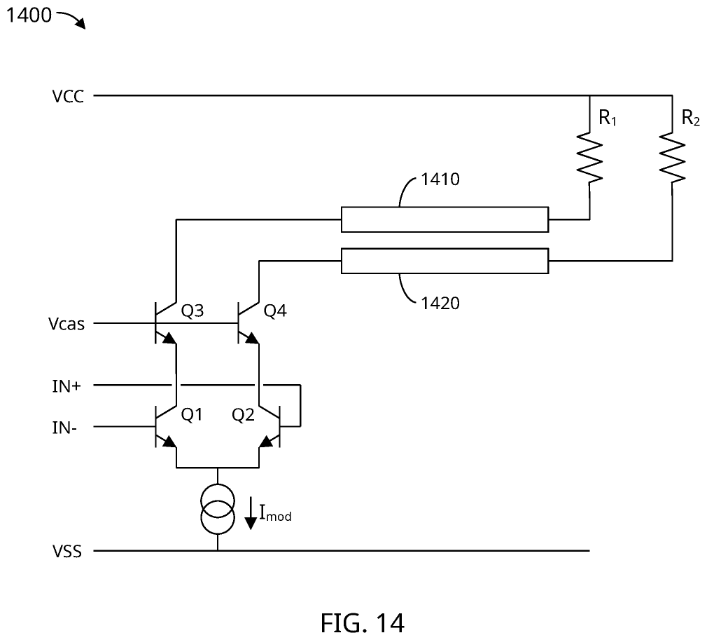

FIG. 14 illustrates an example driver with a modulator in a photonics IC. Again, transistors Q1-Q4 and I_{mod} form a cascoded current switch that switches the modulation current Imo between its outputs that are coupled with the two high-speed phase modulator waveguides (waveguide 1410 and waveguide 1420) in a photonics IC.

### Considerations

Although the description has been described with respect to specific implementations thereof, these specific implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above.

For example, although all examples focus on N-type (NPN) bipolar transistors, other implementations may use FETs, such as MOSFETs. Further implementations may use P-type transistors for some of the circuits. All examples show circuits for differential signals. However, other implementations may use single-ended signals. Although this document provides examples DML, EML, and photonics IC drivers, many other such drivers are known in the art and are fully within the ambit and scope of the technology presented herein, as are other drivers, such as drivers for laser diodes and VCSELs.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although the description has been described with respect to specific implementations thereof, these specific implementations are merely illustrative, and not restrictive. For instance, many of the operations can be implemented on a printed circuit board (PCB) using off-the-shelf devices, in a System-on-Chip (SoC), application-specific integrated circuit (ASIC), programmable processor, a coarse-grained reconfigurable architecture (CGRA), or in a programmable logic device such as a field-programmable gate array (FPGA), obviating the need for at least part of any dedicated hardware. Implementations may be as a single chip, or as a multi-chip module (MCM) packaging multiple semiconductor dies in a single package. All such variations and modifications are to be considered within the ambit of the disclosed technology the nature of which is to be determined from the foregoing description.

Any suitable technology for manufacturing electronic devices can be used to implement the circuits of specific implementations, including CMOS, FinFET, GAAFET, BICMOS, bipolar, JFET, MOS, NMOS, PMOS, HBT, MESFET, etc. Different semiconductor materials can be employed, such as silicon, germanium, SiGe, GaAs, InP, GaN, SiC, graphene, etc. Circuits may have single-ended or differential inputs, and single-ended or differential outputs. Terminals to circuits may function as inputs, outputs, both, or be in a high-impedance state, or they may function to receive supply power, a ground reference, a reference voltage, a reference current, or other. Although the physical processing of signals may be presented in a specific order, this order may be changed in different specific implementations. In some specific implementations, multiple elements, devices, or circuits shown as sequential in this specification can be operating in parallel.

It will also be appreciated that one or more of the elements depicted in the drawings/figures can also be implemented in a more separated or integrated manner, or even removed or rendered as inoperable in certain cases, as is useful in accordance with a particular application.

Thus, while specific implementations have been described herein, latitudes of modification, various changes, and substitutions are intended in the foregoing disclosures, and it will be appreciated that in some instances some features of specific implementations will be employed without a corresponding use of other features without departing from the scope and spirit as set forth. Therefore, many modifications may be made to adapt a particular situation or material to the essential scope and spirit.

What is claimed is:

1. An electronic system, comprising:
a pre-driver circuit;
two or more signal interruption circuits, each with:
a signal interruption circuit enable input;
a signal interruption circuit signal input coupled with a pre-driver circuit signal output; and
a signal interruption circuit signal output; and
two or more driver circuits, each associated with one of the two or more signal interruption circuits, and each with a signal input coupled with the signal interruption circuit signal output of the associated one of the two or more signal interruption circuits.

2. The electronic system of claim 1, further comprising one or more additional pre-driver circuits, and wherein each pre-driver circuit is coupled with one of the two or more signal interruption circuits.

3. The electronic system of claim 1, further comprising an optical device with:
a cathode terminal (K terminal) coupled with a first output terminal of one of the two or more driver circuits; and
an anode terminal (A terminal) coupled with a second output terminal of the one of the two or more driver circuits.

4. The electronic system of claim 3, wherein the optical device is one of:
a laser diode;
a directly modulated laser (DML);
an electro-absorption modulated laser (EML);
a vertical-cavity surface-emitting laser (VCSEL); and
a silicon-photonics device.

5. The electronic system of claim 1, wherein a signal interruption circuit comprises:
a first current switch with differential first current switch current switch inputs, a first current switch first sink output and a first current switch second sink output;
a first transistor of a first type, wherein the first transistor has a first transistor current input terminal, a first transistor current output terminal, and a first transistor control terminal, and wherein the first transistor current input terminal is coupled with a supply voltage node, the first transistor current output terminal is coupled with the first current switch second sink output, and the first transistor control terminal is coupled with a first output of the pre-driver circuit;
a second current switch with second current switch differential current switch inputs, a second current switch first sink output and a second current switch second sink output; and
a second transistor of the first type, wherein the second transistor has a second transistor current input terminal, a second transistor current output terminal, and a second transistor control terminal, and wherein the second transistor current input terminal is coupled with the supply voltage node, the second transistor current output terminal is coupled with the second current switch second sink output, and the second transistor control terminal is coupled with a second output of the pre-driver circuit;
wherein:
the first current switch differential current switch inputs are coupled with the signal interruption circuit enable input;
the second current switch differential current switch inputs are coupled with the signal interruption circuit enable input;
the first transistor current output terminal is further coupled with the signal interruption circuit signal output; and
the second transistor current output terminal is further coupled with the signal interruption circuit signal output.

6. The electronic system of claim 5, wherein the first current switch comprises:
a current sink coupled with a common node; and
a differential pair of transistors of the first type, each with a current input terminal coupled with a first current switch sink output, a control terminal coupled with one of the current switch differential current switch inputs, and a current output terminal coupled with the current sink.

7. The electronic system of claim 5, wherein the signal interruption circuit further comprises:
a first voltage-drop device coupled between the first current switch first sink output and a supply voltage node; and
a second voltage-drop device coupled between the second current switch first sink output and the supply voltage node;
wherein the first voltage-drop device is one of a transistor configured as a diode, a diode, and a resistor.

8. The electronic system of claim 5, wherein the signal interruption circuit further comprises:
a first voltage-drop device coupled between the first current switch first sink output and the signal interruption circuit signal input; and
a second voltage-drop device coupled between the second current switch first sink output and the signal interruption circuit signal input;
wherein the first voltage-drop device is one of a transistor configured as a diode, a diode, and a resistor.

9. The electronic system of claim 5, wherein a transistor of the first type is an N-type transistor.

10. The electronic system of claim 5, wherein the first transistor is one of a bipolar transistor and a field-effect transistor (FET).

11. The electronic system of claim 1, wherein the pre-driver circuit comprises:
a current switch with differential current switch inputs, a first sink output and a second sink output;
a first load resistor and a second load resistor, each with a first terminal coupled with a supply voltage node;
a first cascode transistor with a current input terminal coupled with a second terminal of the first load resistor, a control terminal coupled with a bias voltage source, and a current output terminal coupled with the first sink output of the current switch;
a second cascode transistor with a current input terminal coupled with a second terminal of the second load resistor, a control terminal coupled with the bias voltage source, and a current output terminal coupled with the second sink output of the current switch;
a differential signal input coupled with the differential current switch inputs; and
a differential signal output coupled with the second terminal of the first load resistor and the second terminal of the second load resistor.

12. The electronic system of claim 11, wherein the pre-driver circuit further comprises:
a first follower transistor, with a control input coupled with a first differential input signal terminal, a current input terminal coupled with the supply voltage node and a current output terminal coupled with a first of the differential current switch inputs; and
a second follower transistor, with a control input coupled with a second differential input signal terminal, a current input terminal coupled with the supply voltage node and a current output terminal coupled with a second of the differential current switch inputs.

13. The electronic system of claim 1, wherein the pre-driver circuit comprises:
a current switch with differential current switch inputs, a first sink output and a second sink output;
a first load resistor and a second load resistor, each with a first terminal coupled with a supply voltage node;
a first transistor with a current input terminal coupled with a second terminal of the first load resistor, a control terminal coupled with a first scaler input terminal, and a current output terminal coupled with the first sink output of the current switch;
a second transistor with a current input terminal coupled with a second terminal of the second load resistor, a control terminal coupled with a second scaler input terminal, and a current output terminal coupled with the first sink output of the current switch;
a third transistor with a current input terminal coupled with a second terminal of the first load resistor, a control terminal coupled with the second scaler input terminal, and a current output terminal coupled with the second sink output of the current switch;
a fourth transistor with a current input terminal coupled with a second terminal of the second load resistor, a control terminal coupled with the first scaler input terminal, and a current output terminal coupled with the second sink output of the current switch;
a differential signal input coupled with the differential current switch inputs; and
a differential signal output coupled with the second terminal of the first load resistor and the second terminal of the second load resistor.

14. The electronic system of claim 1, further comprising:
a first capacitor coupled between a first capacitor terminal of one of the two or more driver circuits and a common node; and
a second capacitor coupled between a second capacitor terminal of the one of the two or more driver circuits and the common node.

15. The electronic system of claim 1, further comprising:
an inductor coupled between an output terminal of the one of the two or more driver circuits and an anode supply voltage source.

16. A directly modulated laser driver (DML driver), comprising:
a modulation current sink coupled with a common node;
a bias current sink coupled with the common node;
a first transistor of a first type, wherein the first transistor has a first transistor current input terminal, a first transistor current output terminal, and a first transistor control terminal, and wherein the first transistor current input terminal is coupled with the bias current sink, the first transistor current output terminal is coupled with the modulation current sink, and the first transistor control terminal is coupled with a first driver input terminal;
a second transistor of the first type, wherein the second transistor has a second transistor current input terminal, a second transistor current output terminal, and a second transistor control terminal, and wherein the second transistor current output terminal is coupled with the modulation current sink, and the second transistor control terminal is coupled with a second driver input terminal;
a first termination circuit coupled between the first transistor current input terminal and the common node;
a second termination circuit coupled between the second transistor current input terminal and the common node;
an inductor coupled between an anode voltage supply and the second transistor current input terminal; and
an optical device with a cathode terminal (K terminal) coupled with the first transistor current input terminal and an anode terminal (A terminal) coupled with the second transistor current input terminal;
wherein the first termination circuit comprises a first termination circuit termination resistor and a first termination circuit capacitor coupled in series and the second termination circuit comprises a second termination circuit termination resistor and a second termination circuit capacitor coupled in series.

17. The DML driver of claim 16, wherein the optical device is a directly-modulated laser.

18. The DML driver of claim 16, wherein:
the modulation current sink is programmable.

19. The DML driver of claim 16, wherein:
the bias current sink is programmable.

20. The DML driver of claim 16, wherein:
the first termination circuit termination resistor and the second termination circuit termination resistor are programmable.

21. The DML driver of claim 16, further comprising:
a first voltage-drop device coupled between the second transistor current input terminal and the second termination circuit termination resistor;
wherein the first voltage-drop device is one of a transistor configured as a diode, a diode, and a resistor.

22. The DML driver of claim 16, further comprising:
a pass transistor coupled between the first termination circuit and the second termination circuit.

23. The DML driver of claim 16, wherein a transistor of the first type transistor is an N-type transistor.

24. The DML driver of claim 16, wherein the first transistor is one of a bipolar transistor and a field-effect transistor (FET).
